(19) United States
(12) Patent Application Publication
(10) Pub. No.: US 2018/0323047 A1
(43) Pub. Date: Nov. 8, 2018

(54) SPUTTER TARGET BACKING PLATE ASSEMBLIES WITH COOLING STRUCTURES

(71) Applicant: Honeywell International Inc., Morris Plains, NJ (US)

(72) Inventors: Susan D. Strothers, Mead, WA (US); Kevin B. Albaugh, Liberty Lake, WA (US); Stephane Ferrasse, Spokane, WA (US)

(21) Appl. No.: 15/773,005

(22) PCT Filed: Oct. 27, 2016
(86) PCT No.: PCT/US2016/059121

§ 371 Date: May 2, 2018

Related U.S. Application Data
(60) Provisional application No. 62/254,222, filed on Nov. 12, 2015.

(51) Int. Cl. H01J 37/34; B33Y 10/00; B33Y 70/00; B33Y 80/00

(52) U.S. Cl. CPC H01J 37/3435; B33Y 10/00; B23K 15/0086; B33Y 80/00; B33Y 70/00

(57) ABSTRACT

A method of forming a monolithic backing plate comprising using additive manufacturing to form a three dimensional structure of continuous material including forming a substantially planar first side in a first plane, forming a plurality of flow barriers joined to the first side, the plurality of flow barriers having a thickness in a direction perpendicular to the first plane; forming a plurality of flow channels defined between the plurality of flow barriers; and forming a substantially planar second side in the first plane, and uniformly solidifying the material such that the backing plate comprises a uniform, continuous material structure throughout the first side, the plurality of flow barriers, and the second side.

### TECHNICAL FIELD

The present disclosure relates to backing plate assemblies for use with sputtering targets in physical vapor deposition systems. The present disclosure also relates to backing plates made using additive manufacturing processes which include cooling structures.

### BACKGROUND

Physical vapor deposition methodologies are used extensively for forming thin films of material over a variety of substrates. One area of importance for such deposition technology is semiconductor fabrication. A diagrammatic view of a portion of an exemplary physical vapor deposition (“PVD”) apparatus 8 is shown in FIG. 1. In one configuration, a sputtering target assembly 10 comprises a backing plate 12 having a target 14 bonded thereto. A semiconductive material wafer 18 is within the PVD apparatus 10 and provided to be spaced from the target 14. A surface 16 of target 14 is a sputtering surface. As shown, the target 14 is disposed above the substrate 18 and is positioned such that sputtering surface 16 faces substrate 18. In operation, sputtered material 22 is displaced from the sputtering surface 16 of target 14 and used to form a coating (or thin film) 20 over wafer 18. In some embodiments, suitable substrates 18 include wafers used in semiconductor fabrication.

In an exemplary PVD process, the target 14 is bombarded with energy until atoms from the sputtering surface 16 are released into the surrounding atmosphere and subsequently deposit on substrate 18. In one exemplary use, plasma sputtering is used to deposit a thin metal film onto chips or wafers for use in electronics.

Although monolithic targets are available for some sputtering applications (where monolithic refers to a target formed from a single piece of material without a separate backing plate joined), most targets 14 are joined to a backing plate 12 as depicted in FIG. 1. It is to be understood that the sputtering target 14 and backing plate 12 assembly combined to form a sputtering target assembly 10 depicted in FIG. 1 is an example configuration since both the sputtering target 14 and the backing plate 12 can be any of a number of sizes or shapes as will be understood by those skilled in the art.

The target 14 may be formed from any metal suitable for PVD deposition processes. For example, the target 14 may include aluminum, vanadium, niobium, copper, titanium, tantalum, tungsten, ruthenium, germanium, selenium, zirconium, molybdenum, hafnium, and alloys and combinations thereof. When such exemplary metals or alloys are intended to be deposited as a film onto a surface, a target 14 is formed from the desired metal or alloy, from which metal atoms will be removed during PVD and deposited onto the substrate 18.

The backing plate 12 may be used to support the target 14 during the PVD deposition process. As discussed herein, a PVD deposition process may cause undesirable physical changes to a sputtering target assembly 10 including the target 14, and backing plate 12. For example, the PVD deposition process may include high heat which would cause the target 14 to warp or deform. To prevent this, the sputtering target assembly 10 and components may be designed to reduce these undesirable changes. The properties of the backing plate 12, such as high heat capacity and/or heat conductivity, can help avoid undesirable changes to the target 14 and sputtering target assembly 10.

One option for controlling the properties of the sputtering target assembly 10 includes controlling how the backing plate 12 is formed. This may include controlling the materials that are used and how the materials are treated during the manufacturing process. Another option includes controlling the assembly of the backing plate 12 and the methods used to form the various components of the backing plate 12.

FIG. 2 is a diagrammatic side view of an example sputtering target assembly 10. Sputtering target assemblies are often made by forming a target 14 and backing plate 12 as one piece. FIG. 2 is a diagrammatic view of such a sputtering target assembly 10 formed in a single component design. In the single component design, the material to be sputtered or target material, is strong enough during sputtering that the whole sputtering target assembly 10 can be fabricated from the target material only. Such a single component design can be referred to as a monolithic sputtering target assembly. Some features to note in the monolithic sputtering target assembly 10 are a solid backing plate 12 having a solid interior 42. The sputtering surface 16 faces downward toward a substrate (not shown). Being formed from a single piece of material, the monolithic sputtering target assembly 10 does not have a junction or interface between the material that comprises the target 14 and the material that comprises the backing plate 12. The sputtering target assembly 10 is often bolted at the periphery within the PVD chamber to a target mount plate 28 with the sputtering surface 16 facing downward. The sputtering target assembly 10 as shown, is adjacent to a cooling assembly. In a basic form, a cooling assembly 30 provides cooling fluid 34 such as water to the side of the backing plate opposite the side facing the target 14.

In an example two component sputtering target assembly 10 design, as illustrated in FIG. 3, a backing plate 12 is formed as a separate component from the target 14. The backing plate 12 as shown is a single solid plate. The target 14 is joined to the backing plate 12 by techniques such as fastening, welding, soldering and especially diffusion bonding to form a sputtering target assembly 10. The backing plate 12 provides a variety of functions that include strengthening of mechanical properties and enhancement of physical properties of the whole sputtering target assembly 10. The sputtering target assembly 10 as shown in FIG. 3 includes the target 14 and the backing plate 12 after the two have been joined. Like the single component sputtering target assembly 10 in FIG. 2, the backing plate 12 in FIG. 3 is solid 42. However, the two component design in FIG. 3 introduces an interface 40 where the sputtering target 14 and the backing plate 12 are joined. Even if the target 14 and the backing plate 12 are formed from similar material, the sputtering target assembly 10, when sectioned in a plane normal to the sputtering surface 16, will have a visible interface 40 where the sputtering target material meets or is joined to the backing plate material. The interface 40 is visible as a line separating the sputtering target material and the backing plate material and may be referred to as a bonding line. The bonding line is especially visible when the backing plate 12 and the target 14 are made from different materials.

The sputtering target assembly 10 is bolted to the PVD with a target mount plate 28 and may optionally have a side 32 that is in contact with a cooling system 30. The cooling system 30 is external the sputtering target assembly 10 and cooled by a cooling fluid 34 that runs through the PVD system. Cooling is an important function of sputtering systems and should be carefully engineered to avoid the degradation of mechanical properties of sputtering target assemblies 10 that would be otherwise caused by the high powers needed during PVD deposition.

As illustrated in FIG. 4, a PVD system may include a sputtering target assembly 10 with a more complex cooling system than shown in FIG. 3. In some embodiments, as illustrated in FIG. 4, a hollow backing plate, also referred to as a backing plate assembly 24, may have an internal cooling system built into the backing plate assembly 24. Thus a cooling fluid 34 can be forced into and allowed to circulate inside the sputtering target assembly 10 itself through the backing plate assembly 24, rather than outside the backing plate 12, as in FIG. 3. For example, the backing plate assembly 24 may have an internal cavity also referred to as a cooling chamber 50 within the backing plate assembly 24 itself. To create a sputtering target assembly 10 having a backing plate assembly 24 with an internal cooling chamber 50, the backing plate assembly 24 comprises multiple pieces formed separately which are later combined together to form the backing plate assembly 24.

For example, the sputtering target assembly 10 may include a target 14 joined to a backing plate assembly 24 such as a hollow backing plate. In turn, the backing plate assembly 24 may be formed from combining or joining at least two sides, either of which may have surface structures that form cavities between the two sides for a cooling fluid 34 to flow through once the two sides are joined together.

In some embodiments, a backing plate assembly 24 comprises at least two sides, for example a first side 46 and a second side 48. A first side 46 may be referred to as the backing or insert side. Like the backing plate 12 in FIG. 3, the backing plate assembly 24 in FIG. 4 has a backing side 46 with a bonding surface 40 that is attached or bonded to the target 14. The backing plate assembly 24 includes the backing side 46 joined to a second side 48 that may be referred to as the cooling side. The backing side 46 and the cooling side 46 are joined around their peripheries 52 and define the internal cavity that forms the cooling chamber 50. The cooling chamber 50 holds cooling fluid 34 and allows it to contact the backing side 46 as the cooling fluid 34 flows through the cooling chamber 50. The cooling side 48 allows cooling fluid 34 to be confined within the cooling chamber 50 and draw heat from the target 14 during sputtering operation.

In this disclosure, the backing plate assembly 24 allows cooling fluid 34 to be closer to the target 14 and sputtering target surface 16 and thus more efficiently draw heat from the target 14 via the backing side 46. When the cooling chamber 50 is filled with cooling fluid 34, the backing plate assembly 24 resembles a heat exchanger with the first or backing side 46 defining the heat transfer area.

To cool the backing plate assembly 24, cooling fluid 34 is introduced into the cooling chamber 50 though a fluid input 56 also referred to as a fluid inlet or entrance. The cooling fluid 34 is then allowed to come into contact with the backing side 46. After contacting the backing side 46, the cooling fluid 34 is carried out of the cooling chamber 50 through a cooling fluid output 58 or exit that is in fluid communication with the cooling chamber 50. As shown in FIG. 4, a cooling fluid input 56 may be positioned in a side of the backing plate assembly 24; however, a cooling fluid input 56 may be positioned in any location that allows fluid communication from the outside of the backing plate assembly 24 with the inside of the cooling chamber 50. For example, the cooling fluid input 56 may be positioned through a surface of the cooling side 48. The cooling fluid output 58 or exit may also be located in the side of the backing plate assembly 24, or in any location that allows fluid communication with the cooling chamber 50.

In some embodiments, the cooling chamber 50 may be an open expansive cavity that cooling fluid 34 can flow through. Within the cooling chamber 50, cooling fluid 34 may spread and flow over the entire interior surface of the cooling chamber 50. Generally, cooling fluid 34 may be pumped through the cooling fluid input 56, flow across the interior of the cooling chamber 50, and exit the cooling chamber 50 through the cooling chamber output 58. A cooling fluid flow profile may be controlled by controlling the volumetric flow rate through the cooling chamber 50. For example, a relatively low volumetric flow rate may allow cooling fluid 34 to traverse the cooling chamber 50 with laminar flow. However, in some instances a more turbulent flow profile may be desired, and a higher flow rate may be used.

An exemplary sputtering target assembly 10 with backing plate assembly 24 includes a target 14 that is composed of a target material; for example high purity Al, Cu, or Ti; bonded to a backing side 46, which is itself joined by bonding, brazing or soldering to a cooling side 48. The backing side 46 and cooling sides 48 form the inside cavity for the cooling chamber 50 where the cooling fluid 34 flows. The cooling chamber 50 may contain a plurality of separate channels defined by flow barriers equally partitioned between the backing side 46 and cooling side 48, that force unidirectional fluid flow from a fluid input 56 to a fluid output 58. Additional features are optionally present between the fluid input 56 and fluid output 58 and cooling channels 68; their function is to uniformly distribute cooling fluid 34 in between each cooling channel 68.

In some embodiments, a backing plate assembly 24 is constructed with a relatively planar backing side 46 having a thickness. To form the cooling channels, material is removed from the backing side 46 through a portion of the backing side thickness. This may be completed with a machining tool that removes material. Once the cooling channels are created, the cooling side can be joined to the backing side by joining a surface of the cooling side to the surfaces of the flow barriers. This process is a time and equipment intensive process. The tools used to create the groves are usually expensive, and the material removed to form the cooling channels may be wasted, and is often difficult to recycle.

Another disadvantage of using these methods to form a backing plate assembly 24 is that bonding lines are inherently introduced when multiple components are joined together. As illustrated in FIG. 5, a bonding line 74 is found at an interface where two previously separate components are joined together. For example, the surfaces where any of the backing side 46, the flow barriers 66, or the cooling side 48 are joined may include bonding lines 74 that remain after the components are bonded or welded together. A bonding line 74 can be observed by sectioning the material in a direction normal to the plane of the interface where the two surfaces are joined. The bonding line 74 is often visible even after joining together components having similar material. Bonding lines 74 may introduce structural flaws in the material and provide weak points in the material. Bonding lines 74 are often the site of a material failure when the sputtering target assembly 10 is put in high stress situations such as elevated temperatures or pressures, which are often present in sputtering processes.

The two component design thus inherently gives a bonding line 74 that may potentially introduce weaknesses in the sputtering target assembly 10. For example, when the sputtering target assembly 10 is subjected to high temperatures, such as those reached during a sputtering operation, the backing plate assembly 24 can potentially fail at the bonding line. When the backing plate assembly 24 fails, cooling fluid can leak from the backing plate assembly 24 through the bonding line and reach the inside of a PVD apparatus. Sputtering target assembly failure or backing plate assembly failure may potentially increase when the sputtering target assembly 10 or backing plate assembly 24 are created from two or more different kinds of material. The different materials will have different thermal expansion coefficients and thus will expand at different rates, increasing the likelihood that the bond between the materials will fail.

In addition to the problems introduced with bonding lines 74, larger sized targets 14 and backing plate assemblies 24 increase the complexity of creating cooling channels 68 within a backing plate assembly 24. Also, joining the two sides of the backing plate assembly 24 together after forming cooling channels 68 poses challenges with joining the surfaces of the first side 46 and second side 48 of the backing plate assembly 24 and the surfaces of the flow barriers 66. For example, with cooling channels 68 of extremely tortious flow paths, joining the surfaces of the components of the backing plate assembly 24 requires additional machining time, precise programming and alignment between the various components and at least two joining operations.

### SUMMARY

Disclosed herein, in Example 1, is a method of forming a monolithic backing plate for use with a sputtering target. The method comprises using additive manufacturing to form a three dimensional structure of continuous material. The method includes forming a substantially planar first side in a first plane, the first side having a first surface and a second surface and a thickness between the first and second surface in a direction perpendicular to the first plane. The method further includes forming a plurality of flow barriers joined to the second surface of the first side, the plurality of flow barriers elongated in a direction parallel to the first plane and having a thickness in a direction perpendicular to the first plane. The method further includes forming a plurality of flow channels defined between the plurality of flow barriers and including at least one liquid input and at least one liquid output in fluid communication with the plurality of flow channels. The method includes forming a substantially planar second side in the first plane, the second side having a first surface joined to the plurality of flow barriers and a second surface and a thickness between the first and second surface in a direction perpendicular to the first plane. The method includes uniformly solidifying the material such that the backing plate comprises a uniform, continuous material structure throughout the first side, the plurality of flow barriers, and the second side.

In Example 2, the method of Example 1, wherein forming the backing plate includes forming a single unitary material with no bonding lines between the first side, the plurality of support barriers, and the second side.

In Example 3, the method of any of Examples 1 or 2, wherein the backing plate material is integrally formed throughout the material of the first side, the flow barriers, and the second side.

In Example 4, the method of any of Examples 1 to 3, wherein the material of the monolithic backing is uniformly deposited and solidified to form a single consistent material.

In Example 5, the method of any of Examples 1 to 4, wherein said forming steps are carried out in a single continuous manufacturing process.

In Example 6, the method of any of Examples 1 to 5, further comprising forming the plurality of flow channels such that a liquid can enter the liquid input, flow parallel the first plane between the flow barriers, and exit the liquid exit.

In Example 7, the method of any of Examples 1 to 6, further comprising forming the plurality of flow channels such that a liquid can enter the liquid input, flow parallel the first plane between the flow barriers along a path substantially traversing an area of the second surface of the first side and the first surface of the second side, and exit the liquid output.

In Example 8, the method of any of Examples 1 to 7, further comprising forming the monolithic backing plate from material comprising Al, Co, Cr, Cu, Ta, Ti, Ni, W and their alloys, C, SiC, borides, oxides, and steels.

Disclosed herein, in Example 9, is a method of forming a sputtering target backing plate of continuous material using additive manufacturing. The method comprises repeatedly depositing material layer by layer in a first plane. The method further includes solidifying the deposited material to the previously solidified layer to form a substantially planar first side in a first plane. The first side has a first surface and a second surface defining a thickness between the first and second surface in a direction perpendicular to the first plane. The sputtering target backing plate has a plurality of flow barriers joined to the second surface of the first side. The plurality of flow barriers extend in a direction parallel to the first plane and having a thickness in a direction perpendicular to the first plane. The sputtering target backing plate has a plurality of flow channels defined by the plurality of flow barriers. The sputtering target backing plate has a substantially planar second side in the first plane. The second side has a first surface joined to the flow barriers, and a second surface defining a thickness between the first and second surface in a direction perpendicular to the first plane. The plurality of flow channels are shaped to flow a cooling fluid throughout the backing plate between the second surface of the first side and the first surface of the second side, and the backing plate comprises an integrally uniform material throughout the first side, the plurality of flow barriers, and the second side.

In Example 10, the method of Example 9, wherein forming the backing plate includes forming a single unitary material with no bonding lines between the first side, the plurality of flow barriers, and the second side.

In Example 11, the method of either of Examples 9 or 10, further comprising solidifying the material of the backing plate to form a consistent crystalline structure throughout the material of the first side, the flow barriers, and the second side.

In Example 12, the method of any of Examples 9 to 11, wherein the material of the monolithic backing is uniformly formed as a single material body.

In Example 13, the method of any of Examples 9 to 12, further comprising forming a second plurality of flow barriers to the second side, the second plurality of flow barriers defining a second plurality of flow channels shaped to flow a cooling fluid across the second side.

In Example 14, the method of any of Examples 9 to 13, further comprising forming the monolithic backing plate from material comprising Al, Co, Cr, Cu, Ta, Ti, Ni, W and their alloys, C, SiC, borides, oxides, and steels.

Disclosed herein, in Example 15, is a sputtering target backing plate comprising a first side having a unitary structure formed of a substantially planar continuous material in a first plane. The first side has a first surface and a second surface and a thickness between the first and second surface in a direction perpendicular to the first plane. The sputtering target backing plate includes a second side having a unitary structure formed of a substantially planar continuous material in the first plane and has a first surface, a second surface, and a thickness between the first and second surface in a direction perpendicular to the first plane. The sputtering target backing plate includes a plurality of support barriers joined to the second surface of the first side and the first surface of the second side, the plurality of support barriers having a thickness in the direction perpendicular to the first plane, and elongated in a direction parallel to the first plane such that each of the plurality of support barriers has a length greater than a width in a direction parallel to the first plane. The sputtering target includes a plurality of flow channels defined by the first side, the second side, and the plurality of support barriers and includes a liquid entrance and a liquid exit, such that a liquid can enter the liquid entrance, flow parallel the first plane between the first side and second side, and exit the liquid exit. The backing plate comprises a continuously formed material from the first side, the plurality of support barriers, and the second side.

In Example 16, the backing plate of Example 15, wherein the backing plate comprises a single unitary material with no bonding lines between the first side, the plurality of support barriers, and the second side.

In Example 17, the backing plate of either of Examples 15 and 16, wherein the material of the backing plate is comprised of a single crystalline structure.

In Example 18, the backing plate of any of Examples 15 to 17, wherein the backing plate is formed in a single processing step.

In Example 19, the backing plate of any of Examples 15 to 18, wherein the plurality of flow channels are formed to conduct a liquid through the liquid entrance, carry the liquid between the flow barriers and between first and second side, and exit the liquid exit.

In Example 20, the backing plate of any of Examples 15 to 19, wherein the plurality of flow channels are formed such that a liquid can enter the liquid entrance, flow parallel the first plane between the flow barriers along a path traversing the second surface of the first side and the first surface of the second side, and exit the liquid exit.

In Example 21, the backing plate of any of Examples 15 to 20, wherein the backing plate is formed of material including Al, Co, Cr, Cu, Ta, Ti, Ni, W and their alloys, C, SiC, borides, oxides, and steels.

While multiple embodiments are disclosed, still other embodiments of the present invention will become apparent to those skilled in the art from the following detailed description, which shows and describes illustrative embodiments of the invention. Accordingly, the drawings and detailed description are to be regarded as illustrative in nature and not restrictive.

### BRIEF DESCRIPTION OF THE DRAWINGS

FIG. 1 is a schematic view of a portion of a physical vapor deposition apparatus.

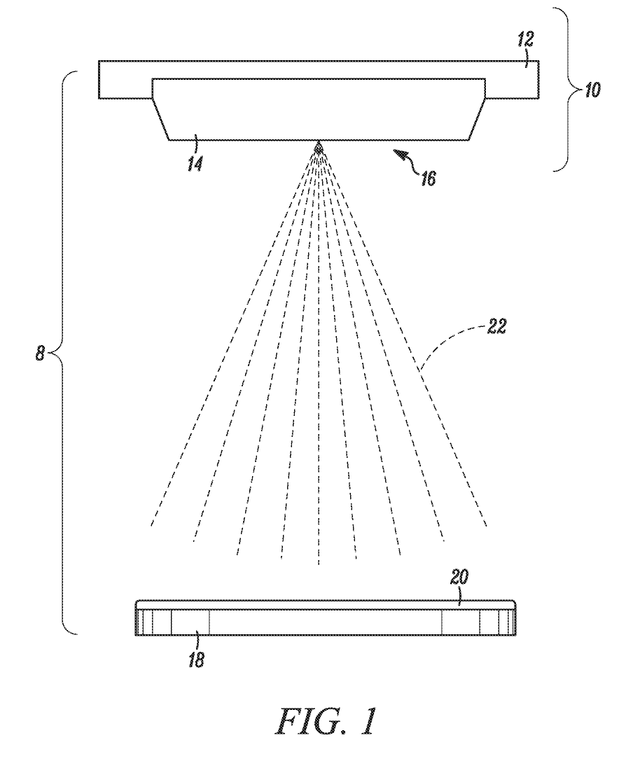

FIG. 2 is a schematic view of a monolithic sputtering target assembly.

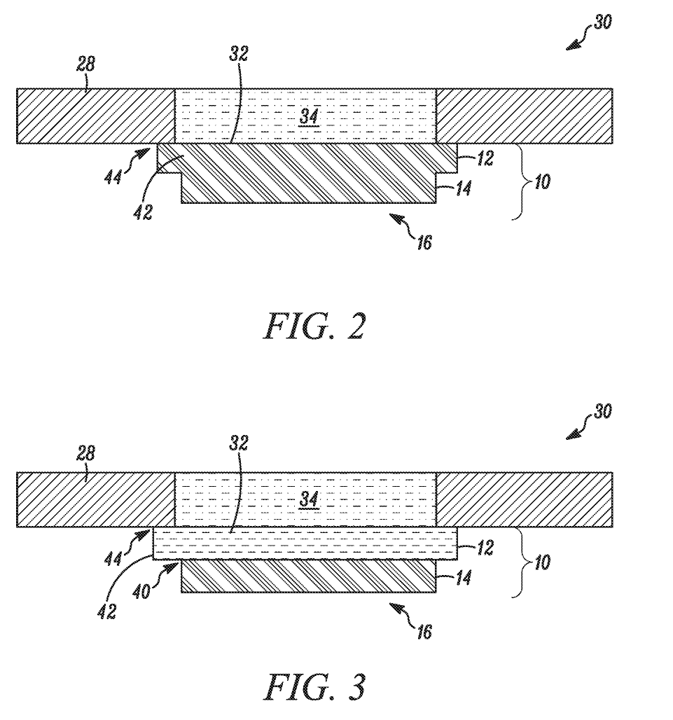

FIG. 3 is a schematic view of a sputtering target and backing plate assembly.

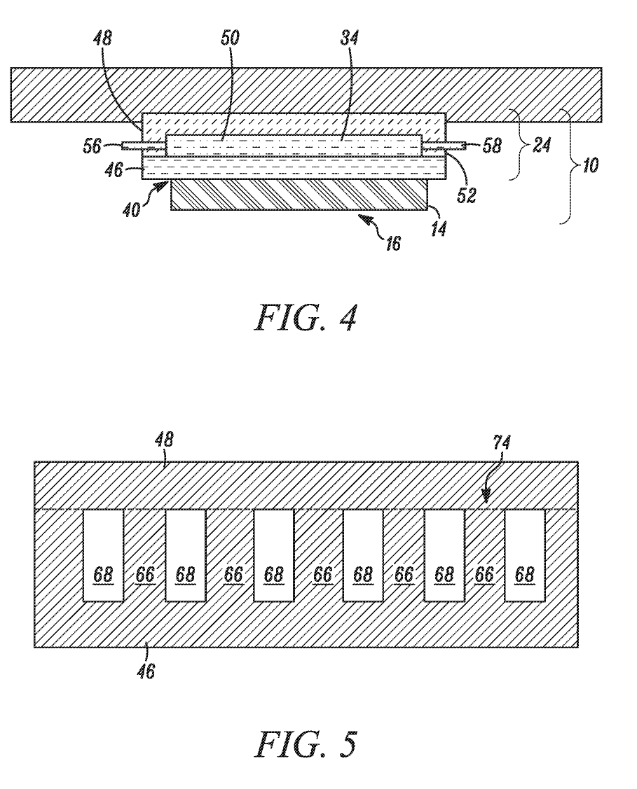

FIG. 4 is a schematic view of a sputtering target assembly having a backing plate with an internal cooling chamber.

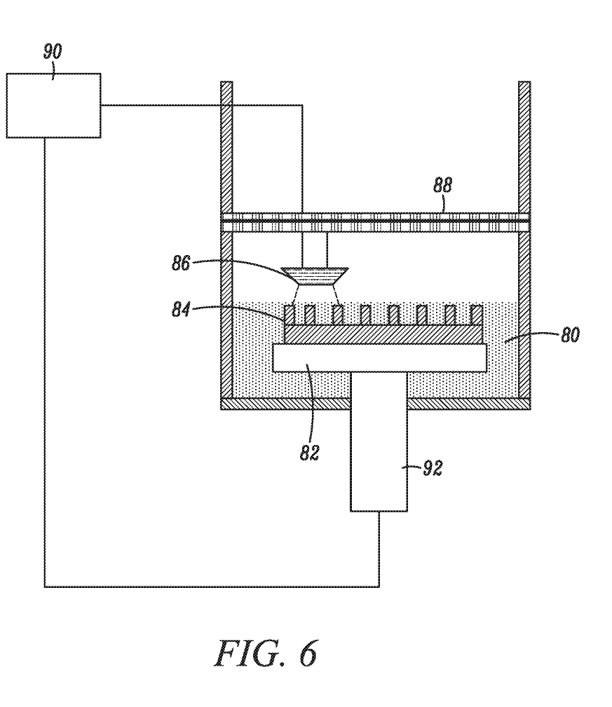

FIG. 5 is a schematic view of a two piece backing plate with cooling channels formed.

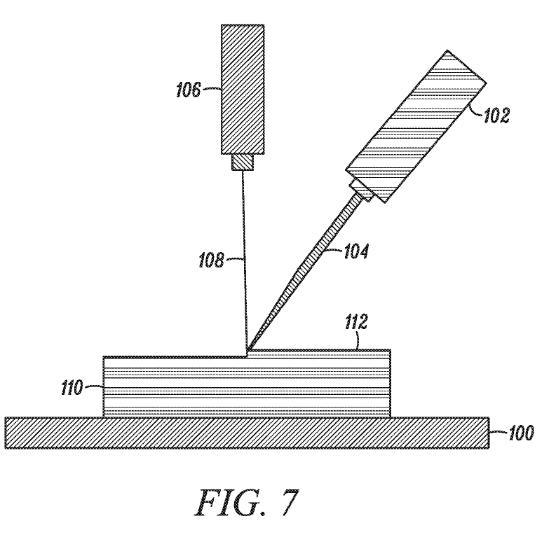

FIG. 6 is a schematic view of an exemplary additive manufacturing device.

FIG. 7 is a schematic view of an exemplary additive manufacturing device.

FIG. 8 is a schematic view of an exemplary additive manufacturing device.

FIG. 9 is a schematic view of an exemplary additive manufacturing device.

FIGS. 10A and 10B are diagrammatic views of methods of forming a backing plate using additive manufacturing.

FIGS. 11A and 11B are diagrammatic views of methods of forming a backing plate using additive manufacturing.

FIG. 12 is a schematic view of an exemplary backing plate with cooling channels.

FIG. 13 is a flowchart of a method according to embodiments of the present disclosure.

FIG. 14 is a flowchart of a method according to embodiments of the present disclosure.

### DETAILED DESCRIPTION

Sputtering target backing plates created from a single piece of material offer potentially improved properties over backing plates constructed from multiple pieces that are fused together. As used herein, the phrase monolithic or monoblock refers to an object such as a backing plate or a sputtering target/backing plate assembly that comprises a single piece of material also referred to as a uniform or integral structure that has been formed in a single additive manufacturing process. As will become apparent in the discussion below, a single additive manufacturing process may include an iterative process with sequential steps.

In some embodiments, the present disclosure pertains to a monolithic sputtering target backing plate that is made from a single piece of material to form a uniform or integral structure having a substantially hollow interior. In some embodiments, the present disclosure pertains to a method of using additive manufacturing to form a monolithic sputtering target backing plate having a uniform or integral structure. In some embodiments, the present disclosure pertains to methods of forming a sputtering target backing plate in a single manufacturing process. In some embodiments, the manufacturing process may be used to form a material with a grain size, density, or composition gradient.

There is a need for a process that can simplify the manufacturing process for creating a backing plate having a cooling chamber. The process used may advantageously be capable of forming a backing plate having no bonding lines between the backing plate components after the materials have been joined. By avoiding the need to remove material from a preformed plate to form cooling channels, the cost and time associated with machining the cooling channels is reduced or eliminated. Further, a manufacturing process that employs only the amount of material needed for the sputtering target assembly decreases the amount of material used, and thus also decreases raw material costs.

Additive manufacturing (“AM”) is a process by which a three dimensional (“3D”) object is created by building up the object in layers by depositing or bonding build material. Design data breaks the 3D object down into individual layers in two dimensional planes and the 3D object is built by adding the exact amount of material needed for each layer in an iterative manner. For this reason, additive manufacturing is also referred to as “3D printing” or “layered manufacturing.” Additive manufacturing techniques include joining or densifying the deposited material via an energy source such as a laser, electron-beam, or ion fusion melting. These techniques are capable of producing net shape, monolithic structures with intricate cavities and channels.

One option is to use these techniques to build monolithic sputtering target and/or backing plate assemblies out of the material to be sputtered with internal cooling channels. Another option is to use additive manufacturing techniques to produce net shaped, single piece backing plates out of non-conventional materials such as composites, laminates or other unique materials either with or without internal cooling channels. These backing plates can then be bonded to the target material. In some embodiments, the introduction of enhanced cooling through internal cooling channels may be sufficient to allow for monolithic sputtering target assemblies having a target without a separate backing plate.

Additive manufacturing can generally be used to form a monolithic backing plate having no discrete bonding lines at an interface between internal flow barriers and a cooling side or backing side. In some embodiments, additive manufacturing can form a backing plate having a unitary material, or integral material, or integrally uniform material defined as a material that does not have discrete bonding lines in the material. For example, a unitary material or integral material is a material that may be sectioned and a path traced along the exposed surface of the solid material after sectioning will not encounter or cross a discrete bonding line.

In some embodiments, the method disclosed herein includes using AM to form a two piece sputtering target assembly including the sputtering target and the backing plate, in which the cooling and backing (also called insert) sides that form the interior cavity, are fabricated during a single step. Using AM, a single fabrication step is possible because of the unique layer by layer deposition sequence of AM methods. In an exemplary method, a sputtering target made by traditional thermo-mechanical processing (“TMP”) such as casting, forging, rolling, or heat treatment that is joined to a backing plate made by AM. The backing plate can be constructed with an internal cavity for circulation of cooling fluid.

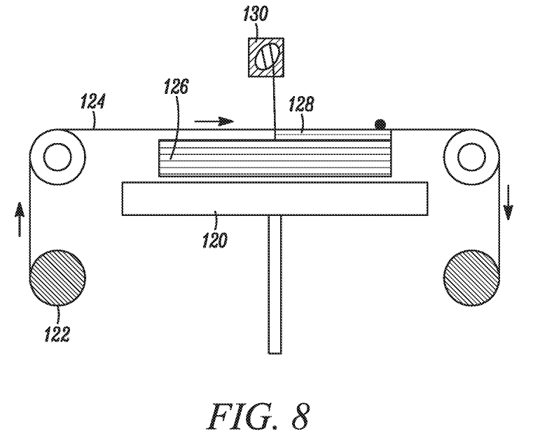

FIG. 6 illustrates a schematic of an example AM device that can be used with the methods of the present disclosure. The example shown in FIG. 6 includes a technique often referred to as powder bed fusion, although a variety of AM techniques may include similar schematics. An AM device may include a bed of build material 80, such as metal or metal alloy powder. The build material 80 may also be deposited layer by layer at the top of a build platform 82 for retaining a three dimensional structure 84 to be built. Build material 80 may be added layer by layer on top of each other and solidified to progressively form the three dimensional structure 84. The build platform 82 is often attached to an elevator 92 that moves up or down relative to the material bed 80 to assist in adding additional layers of build material 80. A melting or curing apparatus 86 is generally positioned above the build platform 86. The curing apparatus 86 may include a device for melting build material 80 such as metal, or may include a curing device for curing laminate or other material. The melting or curing apparatus 86 is often connected to a raster 88 that moves the melting or curing apparatus 86 in relation to the build platform 82 in order melt various locations of the material being built. In some embodiments, an AM apparatus does not have a material bed 80, but instead the melting apparatus 86 includes a dispenser that melts and dispenses material onto the build platform 82 and adds subsequent layers of material to build the three dimensional structure 84. The elevator 92 and melting and curing apparatus 86 are controlled by a control system 90 that governs how the three dimensional structure 84 is built based on the movement of the elevator 92 and melting and curing apparatus 86.

AM is a faster and more precise way of forming complex designs for cooling channels than traditional methods requiring machining and bonding of multiple components. Moreover, because of the superior capabilities of AM technology, new, more efficient channel designs can also be implemented more quickly, some of which may be too complex to be produced by traditional machining techniques. Because sputtering target assembly materials are traditionally made of metals and alloys, disclosed herein are four exemplary types of AM methods that can be used. The four types of AM methods disclosed are powder bed fusion, directed energy deposition, sheet lamination, and binder jetting, although additional methods may become available as technology develops.

Powder Bed Fusion

Powder bed fusion is an AM method in which thermal energy selectively fuses regions of a powder bed 80, such as that shown in FIG. 6. The source of thermal energy is usually a laser or an electron beam. The thermal energy melts a selected portion of a layer of powder material, which then changes to a solid phase as it cools. Another layer of powder is then brought above the powder bed 80 and the recently fused layer, and the process can be repeated again. For metal parts, anchors are typically required to attach the parts to a base plate and support down facing structures. This is necessary due to the high melting point of metal powders that can create a high thermal gradient resulting in thermal stresses and warping if anchors are not used. Other common industrial names for powder bed fusion include laser melting (LM), selective laser melting/sintering (SLM/SLS), direct metal laser sintering (DMLS) and electron beam melting.

Directed Energy Deposition

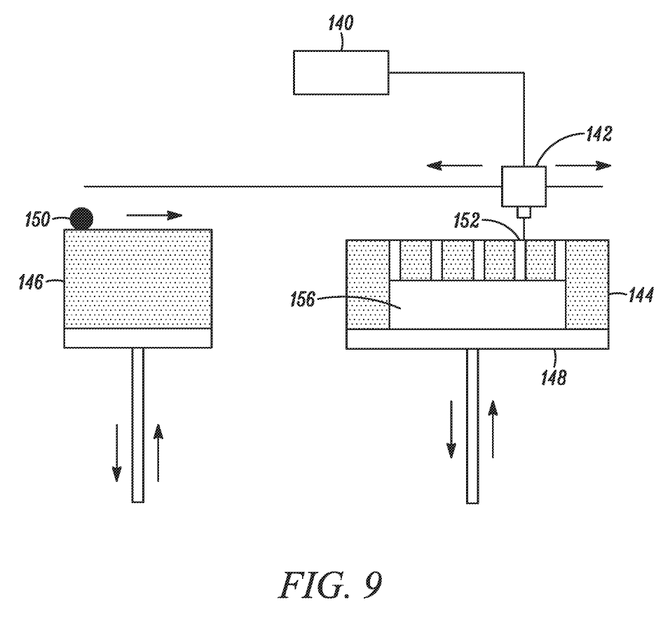

FIG. 7 illustrates a general schematic for directed energy deposition, which uses focused thermal energy to fuse materials by melting the material as it is being deposited. In this process, a build object 110 is created on a solid build platform 100. An arm 102 that is capable of rotating on multiple axes deposits material 104 in the form of a wire or powder. Material 104 is deposited onto existing surfaces 112 of the build object 110. Material 104 is melted using focused energy 108 such as a laser, electron beam or plasma arc, from an energy source 106 that melts the material 104 upon deposition. Further material 104 is added layer by layer and solidifies, creating or repairing new material features on the existing build object 110.

In this technique, typically a laser is the source of energy 108 and the material 104 is a metal powder. In some cases, metal powder is injected or deposited on a pool of molten metal created by the laser. Other names for this technique include blown powder AM and laser cladding. Some unique capabilities include simultaneous deposition of several materials, making functionally graded parts possible. Most directed energy deposition machines also have a 4- or 5-axis motion system or a robotic arm to position the deposition head, so the build sequence is not limited to successive horizontal layers on parallel planes. Hybrid systems can also combine powder-fed directed energy deposition with CNC milling (e.g. 4- or 5-axis milling).

Sheet Lamination

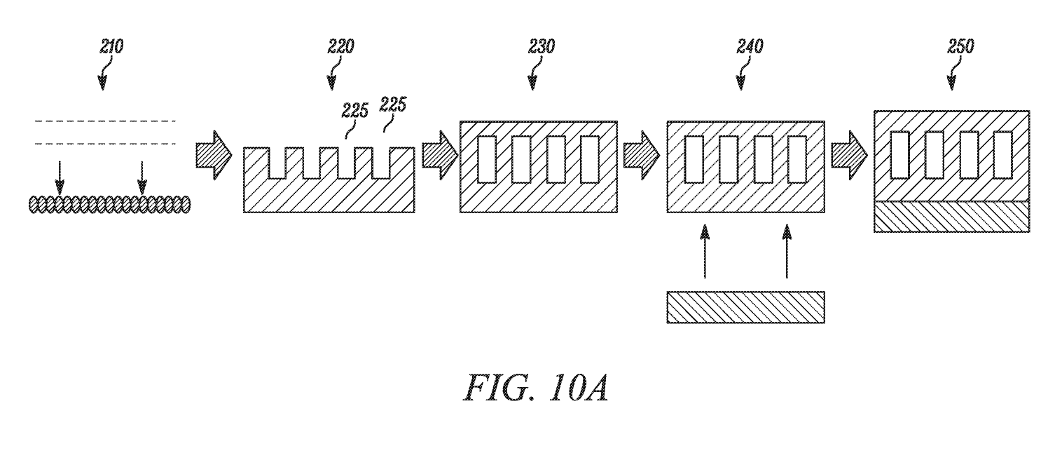

Sheet lamination is an AM process where sheets of material are bonded to form a 3D object. As shown in FIG. 8, preformed sheets 128 of build material are positioned in place on a cutting bed 120 by rollers 122 and optionally additional devices for providing the material sheets 128 such as a belt 124. The material sheets 128 are bonded in place, over the previously bonded layers 126, using an adhesive. The required shape is then cut from the bonded material sheet 128, by a cutting tool 130 such as a laser or knife. The cutting or bonding steps can be reversed and alternatively, the material sheets 128 can be cut before being positioned and bonded.

For metals, sheet materials are often provided in the form of metal tapes or foils. In particular, in ultrasonic additive manufacturing (UAM), metal foils and tapes can also be welded together by a combination of ultrasonic energy supplied by twin high frequency transducers and the compressive force created by the system's rolling sonotrobe. Sheet lamination technology can be combined with full CNC-machining capabilities.

Binder Jetting

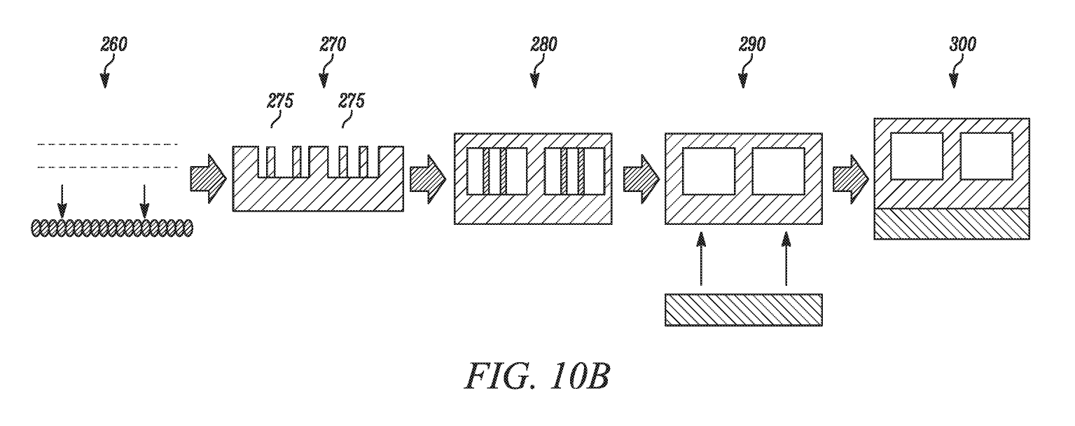

Binder jetting, as shown in FIG. 9 involves a liquid bonding agent selectively dispensed through a liquid adhesive supply 140 deposited through inkjet print head 142 nozzles to join powder materials in a powder bed 144. With binder jetting, the dispensed material is not build material, but rather a liquid that is deposited onto a powder bed 144 to hold the powder in the desired shape. Powder material is moved from a powder supply 146 and spread over the build platform 148 using a roller 150. The print head 142 deposits binder adhesive 152 on top of the powder bed 144 where required. The build platform 148 is lowered as the build object 156 is built. Once the previously deposited layer has been bonded, another layer of powder is spread by the roller 150 over the build object 156 from the powder supply 146. The build object 156 is formed where the powder is bound to the binder adhesive 152. Unbound powder remains in the powder bed 144 surrounding the build object 156. The process is repeated until the entire build object 156 has been made.

Metals parts produced by binder jetting usually must be sintered and infiltrated with a second metal after the AM build process. An example is the use of bronze infiltrant for stainless steel, bronze, or iron parts. Other infiltrants can be Al, glass or carbon fibers. During a post-build furnace cycle, the binder is burned out and bronze is infiltrated into the parts to produce metal alloys.

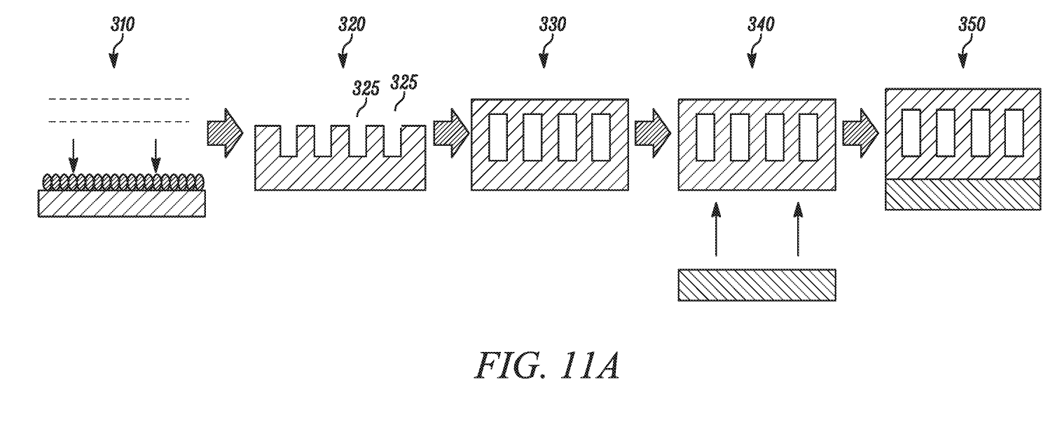

FIGS. 10A and 10B illustrate two methods of using AM techniques to build a sputtering target backing plate having cooling channels. Preferred AM methods include powder bed fusion and directed energy deposition but sheet lamination and binder jetting can be used for some particular metals and alloys.

FIG. 10A shows a method of using AM to build a backing plate assembly without adding internal support structures. In step 210, thermal energy or binding material is used to fuse or bind build material layer by layer to form the backing side. After a suitable thickness has been attained for the backing side, material is deposited in select areas to build up flow barriers in step 220. In some embodiments, flow channels, designated by the arrows 225, can be defined by building up material for the flow barriers, without a need for additional support structures. Once the flow barriers have been built up to a suitable height, the flow channels can be covered by building a cooling side in step 230. The cooling side is also built up layer by layer till it reaches an adequate height. In step 240, the backing plate with flow channels can be removed from the AM machine and undergo additional processing such as cleaning or polishing. A sputtering target can also be added in step 240. In step 250, final bonding steps, such as hipping or welding, are used to fully bond the sputtering target to the backing plate and to ensure the backing plate material is solidified.

FIG. 10B shows a similar method of using AM to build a backing plate assembly as that shown in FIG. 10A, however the method shown in FIG. 10B includes adding internal support structures to the cooling channels. In step 260, material is built layer by layer to form the backing side. In step 270, material is deposited in select areas to build up flow barriers. Then, also in step 270, the build material is used to create the flow barriers and additional support structures 275. In another embodiment, the support structures are pre-formed structures placed on the backing side and then incorporated into the overall constructed using the AM technique. For example, the support structures can be pre-formed and can also be designed with a T-shape structure having a thin wall. Once the flow barriers and support structures have been built up to a suitable height, the flow channels can be covered by building a cooling side in step 280. The support structures assist in bridging the spaces between the flow barriers in order to build up the material that forms the cooling side. The cooling side is built up layer by layer till it reaches an adequate height. In step 290, the backing plate with flow channels can be removed from the AM machine and undergo additional processing such as cleaning or polishing, and the support structures are removed. A sputtering target can also be added in step 290. In step 300, final bonding methods, such as hipping or welding, are used to fully bond the sputtering target to the backing plate and to ensure the backing plate material is solidified.

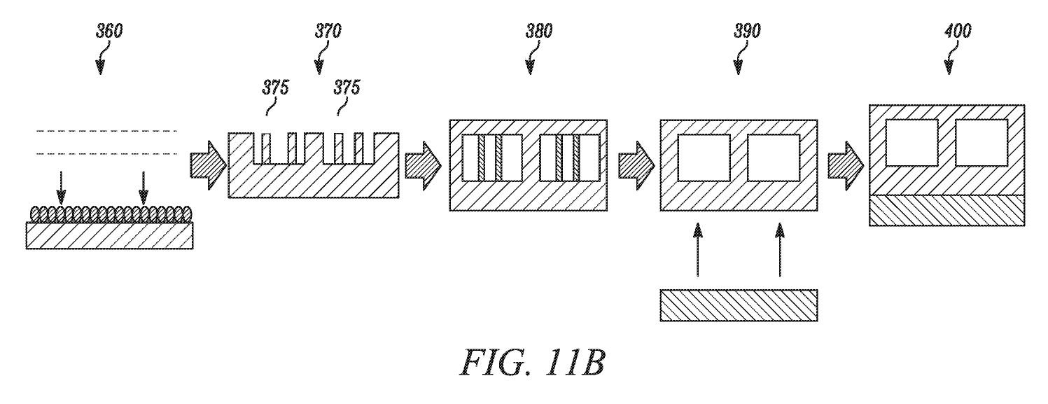

FIGS. 11A and 11B illustrate similar methods of using AM techniques to build a sputtering target backing plate having cooling channels as in FIGS. 10A and 10B, however the starting material includes a preformed plate that comprises part of the backing side. Preferred AM methods include powder bed fusion and directed energy deposition but sheet lamination and binder jetting can be used for some particular metals and alloys.

FIG. 11A shows a method of using AM to build a backing plate assembly without adding internal support structures by starting with a preformed plate. In step 310, the preformed plate is placed into an AM machine and thermal energy or binding material is used to fuse or bind build material layer by layer to the plate to form the entire backing side. Additional steps 320 to 350 in FIG. 11A correspond to steps 220 to 250 in FIG. 10A. In step 320, material is deposited in select areas to build up flow barriers. In some embodiments, flow channels, designated by arrows 325, are created by building up material for the flow barriers, without a need for additional support structures. Once the flow barriers have been built up to a suitable height, the flow channels can be covered by building a cooling side in step 330. The cooling side is built up layer by layer till it reaches an adequate height. In step 340, the backing plate with flow channels can be removed from the AM machine and undergo additional processing such as cleaning or polishing. A sputtering target can also be added in step 340. In step 350, final bonding steps, such as hipping or welding, are used to fully bond the sputtering target to the backing plate and to ensure the backing plate material is solidified.

FIG. 11B shows a similar method of using AM as that shown in FIG. 11A to build a backing plate assembly using a preformed plate as a starting material. However, the method shown in FIG. 11B includes adding internal support structures to the cooling channels. In step 360, the preformed plate is placed into an AM machine and thermal energy or binding material is used to fuse or bind build material layer by layer to the plate to form the entire backing side. In step 370, material is deposited in select areas to build up flow barriers. Then, also in step 370, the build material is used to create the flow barriers and additional support structures 375. In another embodiment, the support structures are pre-formed structures placed on the backing side and then incorporated into the overall constructed using the AM technique. For example, the support structures can be pre-formed and can also be designed with a T-shape structure having a thin wall. Once the flow barriers and support structures have been built up to a suitable height, the flow channels can be covered by building a cooling side in step 380. The support structures assist in bridging the spaces between the flow barriers in order to build up the material that forms the cooling side. The cooling side is built up layer by layer till it reaches an adequate height. In step 390, the backing plate with flow channels can be removed from the AM machine and undergo additional processing such as cleaning or polishing, and the support structures are removed. A sputtering target can also be added in step 390. In step 400, final bonding methods, such as hipping or welding, are used to fully bond the sputtering target to the backing plate and to ensure the backing plate material is solidified.

Materials deposited and used for backing plate material include Al, Co, Cr, Cu, Ta, Ti, Ni, W and their alloys, and steels such as stainless steels. Additional materials such as C or carbon fibers, SiC, borides (B based materials), or oxides (O based materials) can be used for example, as reinforcement material, or incorporated with the metals and alloys used. In some embodiments, composite materials can be formed by AM where silicon carbides (SiC), carbon fibers, borides, or oxides (i.e. Al₂O₃) can be used as reinforcements for the base metals and alloys.

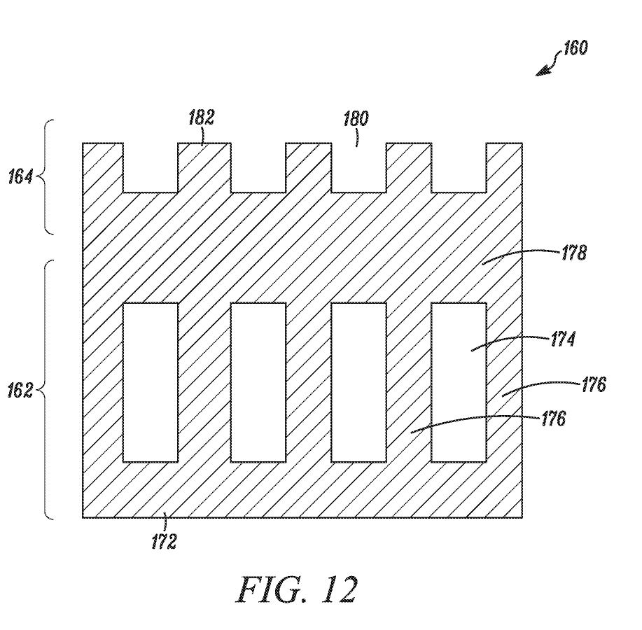

FIG. 12 contains an exemplary embodiment of a backing plate 160 having a first layer 162 and second layer 164. As shown in FIG. 12, the backing plate 160 first layer 162 may be similar to the backing plate described with reference to FIG. 10A, 10B, 11A, or 11B. The first layer 162 may have a backing layer 172, flow barriers 176, flow channels 174, and a cooling layer 178. The backing layer 172, flow barriers 176, flow channels 174, and cooling layer 178 may be similar to those described with reference to FIG. 10A, 10B, 11A, or 11B. The backing layer 172 may be configured to be joined to a target and the flow channels 174 may be configured to direct a cooling fluid, such as water, through the first layer 162 and cool the backing plate 160. As shown in FIG. 12, the backing plate 160 may optionally include the second layer 164 joined to the cooling layer 178. The second layer may include additional flow barriers 182 added to the cooling layer 178. The additional flow barriers 182 define additional flow channels 180. The additional flow channels 180 may be used to carry cooling fluid such as water. The additional flow channels 180 may carry cooling fluid in a direction co-current or counter current to the direction of the flow of cooling fluid in the flow channels 174. The second layer 164 may provide additional cooling to the first layer 162 and overall provide a greater cooling effect to the backing plate 160 than a backing plate that does not have a second layer 164. In some embodiments, the second layer 164 may be formed using methods similar to those shown in FIG. 10A, 10B, 11A, or 11B to form the first layer 162. In some embodiments, additive manufacturing may be used to build the additional flow barriers 182 of the second layer 164 in a layer by layer fashion to form the additional flow channels 180.

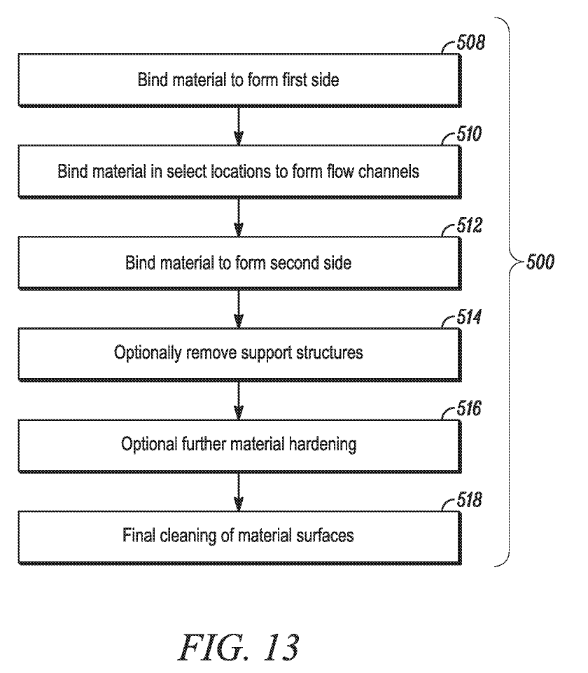

A flow chart of a method 500 of building a backing plate assembly 24 using AM, according to some embodiments, is illustrated in FIG. 13. The method envisions a backing plate assembly 24 built entirely using AM. A first side is created by joining build material using either a melting or binding step 508. In the case of a metal being used, a powdered metal may be melted by the AM apparatus solidified to form a solid layer as a plate or plane. A plane thickness may be increased by subsequently melting and solidifying successive layers over the entire previous layer. Once an adequate thickness has been reached, the AM built plane corresponds to either of the backing side or the cooling side. Next, in step 510, build material may be built up in certain specific locations, instead of the entire surface. In some embodiments, the build material is added in areas that correspond to a flow barrier or barriers.

Additional structures may also be built in addition to the flow barriers to later aid in building a flat plane over the entire structure. Generally, with AM methods involving a large plane built over areas where the previous layer is not bound, support structures should be built. For example, the cooling channels may incorporate support structures or barriers to provide support for building structures above the previously not deposited layers. This is especially useful when channels are not close together. This is also an option for adding support for subsequent layers when creating larger sputtering target backing plates.

After the flow barriers have been built to a suitable height, corresponding to the cooling channel height, a second side is built above the flow barriers in step 512. In this step 512, the build material will have to be added above some areas where a previous layer of build material does not exist. In AM techniques where a powder bed is used, such as powder bed fusion, or powder bed fusion combined with directed energy deposition and binder jetting, the cavities between cooling channels can be made by filling them with loose powders that provide support for building the second side during the build process. One advantage of using the loose powder as a temporary support is that it can eliminate the need for using premade support structures. The loose powder that is used as a temporary support structure can be removed later by flowing an abrasive fluid through the cavities as previously described. In the example of using sheet lamination, no separately built support structures are need when thicker sheets or foils are used as a build material. If premade support structures are needed, often the best design to use is a T-shaped structure with thin walls.

After building a second side in step 512, the entire backing plate apparatus is formed as a solid unit. If support barriers were formed in step 510, they may be removed in step 514 to fully open the flow channels within the cooling chamber. In step 516, the backing plate assembly may undergo further steps to harden the material that has been built by the previous AM steps. For example, if a metal material was built, step 516 may include hardening by subjecting the backing plate to elevated temperatures to allow the metal to recrystallize. Steps 514 and 516 may be carried out in any order, depending on which is more suitable for the particular material used.

Finally, in step 518, once the backing plate is built, the surfaces of the backing plate are optionally cleaned. Cleaning is required to remove metal powder from the parts and the build platform. All excess material should be removed. The AM material is recyclable so it is cost competitive to re-use as much material as possible. In addition, the AM formed parts can go through a post-thermal process where any loose material that is not removed will get trapped inside the parts. The internal cavities in the cooling chamber or cooling channels can be effectively cleaned by abrasive flow machining (AFM). This approach sends an abrasive media through a passage, smoothing out the passage or cavity as the abrasive contacts the internal walls.

Additionally, the outside surfaces of the backing plate may be cleaned by sanding or polishing, or any other cleaning step. In some instances, any external metal support structures may be removed by traditional machining techniques such as grinding or polishing. Alternatively or additionally, the entire backing plate may be cleaned by immersing it in a cleaning fluid or chemical etching, for example. In operation, that excess material could hinder the flow of cooling fluid inside the cooling chamber, and thus should be removed.

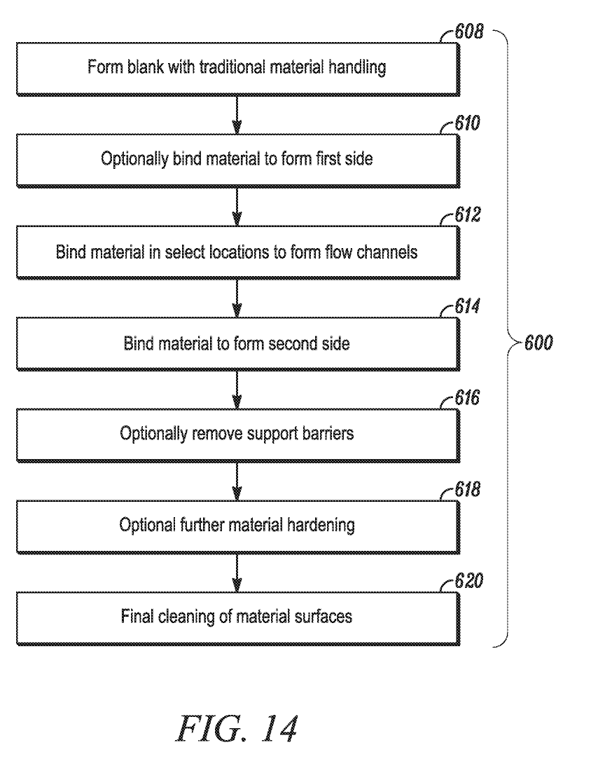

In another exemplary method 600, illustrated in FIG. 14, a blank often in the form of a plate, is used. The blank is processed in step 608 by traditional thermo-mechanical processing and handling techniques such as casting, forging, rolling or ECAE to form the starting material. The blank may already have some machined features added to be the surface of the blank to define the starting structure for flow barriers or cooling channels. The blank is put inside an AM machine and layers of material are integrally formed to the blank and built successively on top of the blank. One advantage of this option is that the starting plate or blank provides a support for the full AM part to be fabricated. A second advantage is that the starting plate will be an integral part of the final product and can provide greater density and higher strength if needed.

In step 610, the blank is optionally further thickened by having additional layers of AM material added to the entire surface of the blank. Alternatively, the blank may be used to comprise the entire first side and the flow channels added directly to the blank in step 612. The subsequent steps in method 600 are similar to the steps in method 500. In step 612, build material is built up in certain specific locations, instead of the entire surface. In some embodiments, the build material is added in areas that correspond to a flow barrier or barriers. Additional structures may also be built in addition to the flow barriers to later aid in building a flat plane over the entire structure.

After the flow barriers have been built to a suitable height, corresponding to the cooling channel height, a second side is built above the flow barriers in step 614. In this step 614, the build material will have to be added above some areas where a previous layer of build material does not exist. In AM techniques where a powder bed is used, such as powder bed fusion, or powder bed fusion combined with directed energy deposition and binder jetting, the cavities between cooling channels can be made by filling them with loose powders that provide support for building the second side. One advantage of using the loose powder as a temporary support is that it can eliminate the need for using premade support structures. The loose powder that is used as a temporary support structure can be removed later by flowing an abrasive fluid through the cavities as previously described. In the example of using sheet lamination, no separately built support structures are need when thicker sheets or foils are used as a build material.

After building a second side in step 614, the entire backing plate apparatus is formed as a solid unit. If support barriers were formed in step 612, they may be removed in step 616 to fully open the flow channels within the cooling chamber. In step 618, the backing plate assembly may undergo further steps to harden the material that has been built by the previous AM steps. For example, if a metal material was built, step 618 may include hardening by subjecting the backing plate to elevated temperatures to allow the metal to recrystallize. Steps 616 and 618 may be carried out in any order, depending on which is more suitable for the particular material used.

Finally, in step 620, once the backing plate is built, the surfaces of the backing plate are optionally cleaned. Cleaning is required to remove metal powder from the parts and the build platform. All excess material should be removed. In addition, the AM formed parts can go through a post-thermal process where any loose material that is not removed will get trapped inside the parts. The internal cavities in the cooling chamber or cooling channels can be effectively cleaned by abrasive flow machining (“AFM”).

Additionally, the outside surfaces of the backing plate may be cleaned by sanding or polishing, or any other cleaning step. In some instances, any external metal support structures may be removed by traditional machining techniques such as grinding or polishing. Alternatively or additionally, the entire backing plate may be cleaned by immersing it in a cleaning fluid or chemical etching, for example. In operation, that excess material could hinder the flow of cooling fluid inside cavity, and thus should be removed.

Additional post AM thermal processing may be carried out in steps 516 and 618 to relieve stress and impart better mechanical properties in the AM produced parts. For example, thermal processing may include recrystallization or hipping. A multistep process may include a variety of thermal processing methods. Stress relief may first be conducted at low temperatures well below static recrystallization of a given material. Hot isostatic pressing (HIP) or hipping may optionally also be performed to remove any micro-porosity or any other micro-defect such as micro-cracks. As an additional treatment, the AM produced part can be solution heat treated. The AM produced part may also be precipitation hardened in order to harden and improve homogeneity of the material. These steps may be employed either singly or in combination to affect and change the microstructure. One option is to use thermal bonding to join the target material and the AM processed backing plate with an internal cavity by hipping in order to simultaneously bond the target assembly together and thermally treat the AM build part.

Additive manufacturing may thus allow a manufacturer to create a sputtering target backing plate as a single piece of continuous material in a single manufacturing step. Creating the backing plate of a continuous material leads to less plastic deformation during use. This is especially useful because conventional high power/high throughput sputtering targets for thin film deposition onto 300 mm or 450 mm wafers have been observed to experience deflection when in use. These targets are typically manufactured with aluminum or copper alloy backing plate materials and are cooled in service via water cooling on the back side of the backing plate. Demands on the mechanical integrity of target assemblies and the requirements for dissipation of heat increase as targets increase in diameter to facilitate greater diameter wafer sputtering. There is thus a need for stronger, more rigid backing plate materials such as composites, laminated structures, and non-conventional materials. In addition, new target assemblies often benefit from internal cooling channels to increase thermal conductivity and dissipation. Conventional methods of producing composites and laminated structures is often cost prohibitive. Conventional methods of producing internal cooling channels require multiple piece brazing, soldering or diffusion bonding. These methods are also expensive, involving multiple steps with each interface creating an opportunity for a defect in the overall target assembly.

Plastic deformation at elevated temperatures can be detrimental for backing plates, especially those made from material with high strength yet low ductility. Backing plates made from the methods described herein have as one advantage an increased resistance to plastic deformation. An increased resistance to plastic deformation is desirable in a backing plate as it allows the backing plate to maintain its original shape, even when subjected to high temperatures such as those experienced during sputtering operations.

Having a monolithic structure that does not bow or bend even when subjected to high temperatures allows the backing plate to stay in contact with the sputtering target across the entire interface between the target and the backing plate throughout the entire lifetime of the sputtering target. A backing plate that is made as a single continuous piece of material also has greater structural integrity as there are no bonding lines at an interface where two or more pieces of material are fused together. This allows for longer, more efficient use of the sputtering target and decreases interruptions in the sputtering process.

Various modifications and additions can be made to the exemplary embodiments discussed without departing from the scope of the present invention. For example, while the embodiments described above refer to particular features, the scope of this invention also includes embodiments having different combinations of features and embodiments that do not include all of the above described features.

The following is claimed:

1-10. (canceled)

11. A method of forming a monolithic backing plate for use with a sputtering target, the method comprising:
using additive manufacturing to form a three dimensional structure of continuous material including
forming a substantially planar first side in a first plane, the first side having a first surface and a second surface and a thickness between the first and second surface in a direction perpendicular to the first plane;
forming a plurality of flow barriers joined to the second surface of the first side, the plurality of flow barriers elongated in a direction parallel to the first plane and having a thickness in a direction perpendicular to the first plane;
forming a plurality of flow channels defined between the plurality of flow barriers and including at least one liquid input and at least one liquid output in fluid communication with the plurality of flow channels; and
forming a substantially planar second side in the first plane, the second side having a first surface joined to the plurality of flow barriers and a second surface and a thickness between the first and second surface in a direction perpendicular to the first plane, and
solidifying the material such that the backing plate comprises a uniform, continuous material structure throughout the first side, the plurality of flow barriers, and the second side.

12. The method of claim 11, wherein forming the backing plate includes forming a single unitary material with no bonding lines between the first side, the plurality of flow barriers, and the second side.

13. The method of claim 11, wherein the backing plate material is integrally formed throughout the material of the first side, the flow barriers, and the second side.

14. The method of claim 11, wherein the material of the monolithic backing is uniformly deposited and solidified to form a single consistent material.

15. The method of claim 11, wherein said forming steps are carried out in a single continuous manufacturing process.

16. The method of claim 11, further comprising forming the plurality of flow channels such that a liquid can enter the liquid input, flow parallel the first plane between the flow barriers, and exit the liquid output.

17. The method of claim 11, further comprising forming the plurality of flow channels such that a liquid can enter the liquid input, flow parallel the first plane between the flow barriers along a path substantially traversing an area of the second surface of the first side and the first surface of the second side, and exit the liquid output.

18. The method of claim 11, further comprising forming the monolithic backing plate from material comprising Al, Co, Cr, Cu, Ta, Ti, Ni, W and their alloys, C, SiC, borides, oxides, and steels.

19. A method of forming a sputtering target backing plate of continuous material using additive manufacturing, the method comprising:
repeatedly depositing material layer by layer in a first plane; and
solidifying the deposited material to a previously solidified layer to form
a substantially planar first side in the first plane, the first side having a first surface and a second surface defining a thickness between the first and second surface in a direction perpendicular to the first plane;
a plurality of flow barriers joined to the second surface of the first side, the plurality of flow barriers extended in a direction parallel to the first plane and having a thickness in a direction perpendicular to the first plane;
defining a plurality of flow channels with the plurality of flow barriers; and
a substantially planar second side in the first plane, the second side having a first surface joined to the flow barriers and a second surface defining a thickness between the first and second surface in a direction perpendicular to the first plane,
wherein the plurality of flow channels are shaped to flow a cooling fluid throughout the backing plate between the second surface of the first side and the first surface of the second side, and
wherein the backing plate comprises an integrally uniform material throughout the first side, the plurality of flow barriers, and the second side.

20. The method of claim 19, wherein forming the backing plate includes forming a single unitary material with no bonding lines between the first side, the plurality of flow barriers, and the second side.

21. The method of claim 19, further comprising solidifying the material of the backing plate to form a consistent crystalline structure throughout the material of the first side, the flow barriers, and the second side.

22. The method of claim 19, wherein the material of the monolithic backing is uniformly formed as a single material body.

23. The method of claim 19, further comprising forming a second plurality of flow barriers to the second side, the second plurality of flow barriers defining a second plurality of flow channels shaped to flow a cooling fluid across the second side.

24. The method of claim 19, further comprising forming the monolithic backing plate from material comprising Al, Co, Cr, Cu, Ta, Ti, Ni, W and their alloys, C, SiC, borides, oxides, and steels.

25. A sputtering target backing plate comprising:
a first side having a unitary structure formed of a substantially planar continuous material in a first plane and having a first surface and a second surface and a thickness between the first and second surface in a direction perpendicular to the first plane;
a second side having a unitary structure formed of a substantially planar continuous material in the first plane and having a first surface and a second surface and a thickness between the first and second surface in a direction perpendicular to the first plane;
a plurality of support barriers joined to the second surface of the first side and the first surface of the second side, the plurality of support barriers having a thickness in the direction perpendicular to the first plane, and elongated in a direction parallel to the first plane such that each of the plurality of support barriers has a length greater than a width in a direction parallel to the first plane;
a plurality of flow channels defined by the first side, the second side, and the plurality of support barriers and including a liquid entrance and a liquid exit, such that a liquid can enter the liquid entrance, flow parallel the first plane between the first side and second side, and exit the liquid exit;
wherein the backing plate comprises a continuously formed material from the first side, the plurality of support barriers, and the second side.

26. The backing plate of claim 25, wherein the backing plate comprises a single unitary material with no bonding lines between the first side, the plurality of support barriers, and the second side.

27. The backing plate of claim 25, wherein the material of the backing plate is comprised of a single crystalline structure.

28. The backing plate of claim 25, wherein the backing plate is formed in a single processing step.

29. The backing plate of claim 25, wherein the plurality of flow channels are formed to conduct a liquid through the liquid entrance, carry the liquid between the flow barriers and between first and second side, and exit the liquid exit.

30. The backing plate of claim 25, wherein the backing plate is formed of material including Al, Co, Cr, Cu, Ta, Ti, Ni, W and their alloys, C, SiC, borides, oxides, and steels.
